(19) United States
(12) Patent Application Publication
(10) Pub. No.: US 2026/0173674 A1
(43) Pub. Date: Jun. 18, 2026

(54) DISPLAY DEVICE

(71) Applicant: LG Display Co., Ltd., Seoul (KR)

(72) Inventors: Sung-Gon HONG, Paju-si (KR); Chang-Heon KANG, Paju-si (KR); Jong-Chan PARK, Paju-si (KR); Dong-Hyun YEO, Paju-si (KR)

(73) Assignee: LG Display Co., Ltd., Seoul (KR)

(21) Appl. No.: 19/194,910

(22) Filed: Apr. 30, 2025

(30) Foreign Application Priority Data
Dec. 13, 2024 (KR) 10-2024-0185689

(51) Int. Cl. H10K 59/126; H10K 59/122; H10K 59/131; H10K 59/80

(52) U.S. Cl. CPC H10K 59/126; H10K 59/122; H10K 59/131; H10K 59/873

(57) ABSTRACT

A display device can include a display area, and a non-display area including a first mesh area, a second mesh area between the first mesh area and the display area, and a bank open area between the first and second mesh areas. Also, the display device can include a light emitting diode in the display area and including an anode, a light emitting layer and a cathode, a conductive mesh layer including a first conductive mesh pattern in the first mesh area, a second conductive mesh pattern in the second mesh area and a third conductive mesh pattern in the bank open area, a bank in the first and second mesh areas and exposing the third conductive mesh pattern, a contact electrode overlapping the bank in the second mesh area and connected to the third conductive mesh pattern, and a spacer on the bank in the first mesh area.

### CROSS-REFERENCE TO RELATED APPLICATIONS

The present application claims priority to Korean Patent Application No. 10-2024-0185689 filed in the Republic of Korea on Dec. 13, 2024, the entirety of which is hereby incorporated by reference into the present application.

### BACKGROUND

### Technical Field

The present disclosure relates to a display device, and more specifically, to a display device capable of preventing static electricity from being generated between a deposition mask and a conductive mesh layer in a non-display area.

### Discussion of Background Art

Recently, a requirement for flat panel display devices having a small, occupied area has been increasing. Among flat panel display devices, a technology of an organic light emitting display device, which includes an organic light emitting diode (OLED), and an inorganic light emitting display device, which includes an inorganic light emitting diode, is rapidly developing.

For example, the OLED includes a cathode as an electron injection electrode, an anode as a hole injection electrode and an organic light emitting layer, which is disposed between the cathode and the anode and includes a host and a dopant. When electrons from the cathode and holes from the anode enter into the organic light emitting layer, the electrons and holes are combined to generate an exciton, and the exciton is transformed from an excited state to a ground state. As a result, the light is emitted from the OLED.

A deposition mask can be used in a deposition process for fabricating the organic light emitting display device. However, in the deposition process, static electricity can be generated between a deposition mask and a conductive mesh layer in a non-display area which can generate a defect in the display device. Also, a need exists for a display device having a configuration that can effectively balance an ability to provide effective outgassing of harmful gasses and providing protection against damaging static electrical discharge or sparks during fabrication.

### SUMMARY OF THE DISCLOSURE

The present disclosure is directed to a display device that substantially obviates one or more of the problems associated with the limitations and disadvantages of the related conventional art.

An object of the present disclosure is to provide a display device capable of preventing or minimizing generation of static electricity in a fabricating process.

An object of the present disclosure is to prevent or reduce defects in a display device and improve a production yield of the display device.

An object of the present disclosure is to provide a display device including a conductive mesh pattern, which is formed for out-gassing from a planarization layer, with a relatively small width that is capable of preventing a burnt problem of the conductive mesh pattern.

An object of the present disclosure is to decrease a resistance of the conductive mesh pattern by alternately arranging holes of the conductive mesh patterns.

An object of the present disclosure is to uniformly coat an encapsulation layer by forming the conductive mesh pattern to have pointed ends and arranging the pointed ends to face each other.

Additional features and advantages of the present disclosure are set forth in the description which follows, and will be apparent from the description, or evident by practice of the present disclosure. The objectives and other advantages of the present disclosure are realized and attained by the features described herein as well as in the appended drawings.

To achieve these and other advantages in accordance with the purpose of the embodiments of the present disclosure, as described herein, an aspect of the present disclosure is a display device having a substrate including a display area and a non-display area at an outer side of the display area, the non-display area including a first mesh area, a second mesh area between the first mesh area and the display area and a bank open area between the first and second mesh area; a light emitting diode disposed in the display area and including an anode, a light emitting layer and a cathode; a conductive mesh layer including a first conductive mesh pattern in the first mesh area, a second conductive mesh pattern in the second mesh area and a third conductive mesh pattern in the bank open area; a bank disposed in the first and second mesh areas and exposing the third conductive mesh pattern in the bank open area; a contact electrode covering the bank in the second mesh area and connected to the third conductive mesh pattern in the bank open area; and a spacer disposed on the bank in the first mesh pattern.

It is to be understood that both the foregoing general description and the following detailed description are explanatory and are intended to further explain the present disclosure as claimed.

### BRIEF DESCRIPTION OF THE DRAWINGS

The accompanying drawings, which are included to provide a further understanding of the present disclosure and are incorporated in and constitute a part of this specification, illustrate embodiments of the present disclosure and together with the description serve to explain the principles of the present disclosure.

FIG. 1 is a schematic view illustrating a display device according to an embodiment of the present disclosure.

FIG. 2 is a schematic cross-sectional view illustrating a display device in a pixel region according to an embodiment of the present disclosure.

FIG. 3A is a schematic plane view illustrating a display device in a non-display area according to an embodiment of the present disclosure.

FIG. 3B is a schematic cross-sectional taken along the line I-I′ of FIG. 3A according to an embodiment of the present disclosure.

FIG. 4A is a schematic plane view illustrating a display device in a non-display area according to another embodiment of the present disclosure.

FIG. 4B is a schematic cross-sectional taken along the line II-II′ of FIG. 4A according to an embodiment of the present disclosure.

FIG. 5 is a schematic cross-sectional view illustrating a display device in a non-display area according to an embodiment of the present disclosure.

FIG. 6 is a schematic cross-sectional view illustrating a display device in a non-display area according to another embodiment of the present disclosure.

FIG. 7 is a schematic cross-sectional view illustrating a display device in a non-display area according to an embodiment of the present disclosure.

FIG. 8 is a schematic cross-sectional view illustrating a display device in a non-display area according to an embodiment of the present disclosure.

FIG. 9 is a schematic plane view illustrating a display device in a non-display area according to another embodiment of the present disclosure.

FIG. 10 is a schematic plane view illustrating a display device in a non-display area according to an embodiment of the present disclosure.

### DETAILED DESCRIPTION OF THE EMBODIMENTS

Reference will now be made in detail to aspects of the present disclosure, examples of which can be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and can be changed as is known in the art, with the exception of steps and/or operations necessarily occurring in a particular order. Like reference numerals designate like elements throughout. Names of the respective elements used in the following explanations are selected only for convenience of writing the specification and can be thus different from those used in actual products.

Advantages and features of the present disclosure and methods of achieving them will be apparent with reference to the aspects described below in detail with the accompanying drawings. However, the present disclosure is not limited to the aspects disclosed below, but can be realized in a variety of different forms, and only these aspects allow the disclosure of the present disclosure to be complete. The present disclosure is provided to fully inform the scope of the disclosure to the skilled in the art of the present disclosure.

The shapes, sizes, proportions, angles, numbers, and the like disclosed in the drawings for explaining the aspects of the present disclosure are illustrative, and the present disclosure is not limited to the illustrated matters. The same reference numerals refer to the same elements throughout the specification. In addition, in describing the present disclosure, if it is determined that a detailed description of the related known technology unnecessarily obscure the subject matter of the present disclosure, the detailed description thereof can be omitted. When “including,” “having,” “consisting,” and the like are used in this specification, other parts can be added unless “only” is used. When a component is expressed in the singular, situations including the plural are included unless specific statement is described.

The expression “at least one of a, b, and c” described throughout the specification can encompass “a alone,” “b alone,” “c alone,” “a and b,” “a and c,” “b and c,” or “all of a, b, and c.” The advantages and features of the present invention, and the methods for achieving them, will become apparent by referring to the embodiments described in detail below together with the accompanying drawings.

In construing an element, the element is construed as including an error or tolerance range although there is no explicit description of such an error or tolerance range.

In describing a position relationship, for example, when a position relation between two parts is described as, for example, “on,” “over,” “under,” and “next,” one or more other parts can be disposed between the two parts unless a more limiting term, such as “just” or “direct(ly)” is used.

In describing a time relationship, for example, when the temporal order is described as, for example, “after,” “subsequent,” “next,” and “before,” a situation that is not continuous can be included unless a more limiting term, such as “just,” “immediate(ly),” or “direct(ly)” is used.

The area, length, or thickness of each component described in the specification is illustrated for convenience of explanation, and the present invention is not necessarily limited to the area and thickness of the illustrated component.

It will be understood that, although the terms “first,” “second,” etc. can be used herein to describe various elements, these elements should not be limited by these terms. These terms are only used to distinguish one element from another. For example, a first element could be termed a second element, and, similarly, a second element could be termed a first element, without departing from the scope of the present disclosure.

Features of various aspects of the present disclosure can be partially or overall coupled to or combined with each other, and can be variously inter-operated with each other and driven technically as those skilled in the art can sufficiently understand. The aspects of the present disclosure can be carried out independently from each other, or can be carried out together in co-dependent relationship. Also, the term “can” used herein includes all meanings and definitions of the term “may.”

Without specific description, a transistor constituting the pixel circuit embodiments of the present disclosure can include at least one of an oxide thin film transistor (Oxide TFT), an amorphous silicon TFT (a-Si TFT), and a low temperature poly silicon (LTPS) TFT.

The following embodiments are described with reference to organic light emitting display devices. However, the embodiments of the present disclosure are not limited to organic light emitting display devices. For example, a display device according to an embodiment of the present disclosure can be an organic light emitting display device using an organic light emitting material or an inorganic light emitting display device using an inorganic light emitting material such as a quantum dot.

Reference will now be made in detail to some of the example embodiments, which are illustrated in the accompanying drawings.

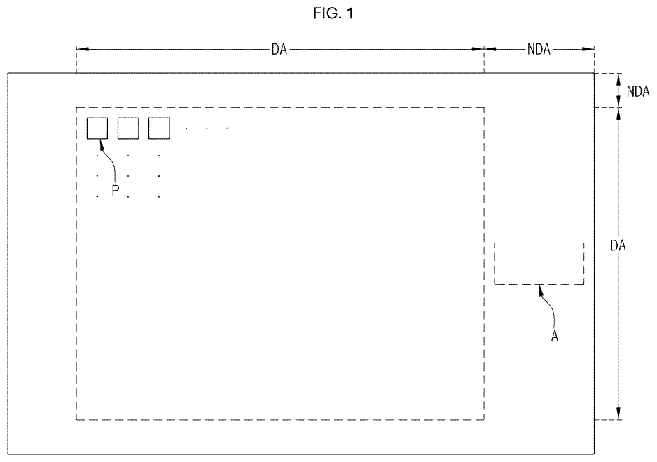

FIG. 1 is a schematic view illustrating a display device according to an embodiment of the present disclosure.

As shown in FIG. 1, an organic light emitting display device includes a display area DA and a non-display area NDA at an outer side of the display area DA. For example, the non-display area NDA can surround the display area DA.

A pixel region P is defined in the display area DA. For example, the pixel region P can include a red pixel region, a green pixel region and a blue pixel region. In addition, the pixel region P can further include a white pixel region.

A driving circuit, e.g., a data driving unit or a gate driving unit, and a signal line, e.g., a low potential voltage line, can be disposed in the non-display area NDA.

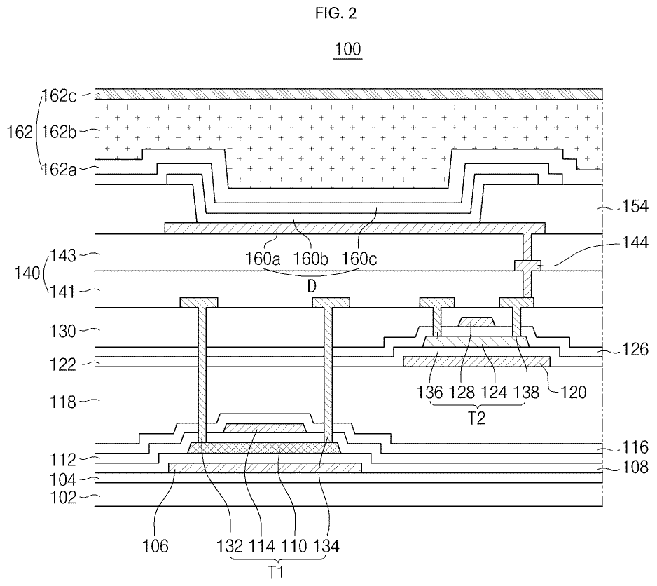

FIG. 2 is a schematic cross-sectional view illustrating a display device in on pixel region of the present disclosure.

As shown in FIG. 2, a display device 100 includes a substrate 102 including a pixel region P, a planarization layer 140 over the substrate 102, a light emitting diode D corresponding to the pixel region P and disposed on the planarization layer 140 and a bank (e.g., a pixel definition layer) 154 corresponding to a boundary of the pixel region P and disposed on the planarization layer 140.

A display area DA and a non-display area NDA at an outer side of the display area DA are defined on the substrate 102. For example, the non-display area NDA can surround the display area DA. The plurality of pixel regions P are defined in the display area DA, and an emission area EA and a non-emission area NEA are defined in each of the plurality of pixel regions P.

The substrate 102 can be a glass substrate or a flexible substrate. For example, the substrate 102 can be a polyimide (PI) substrate, a polyethersulfone (PES) substrate, a polyethylenenaphthalate (PEN) substrate, a polyethylene terephthalate (PET) substrate or a polycarbonate (PC) substrate.

In an aspect of the present disclosure, the substrate 103 can have a triple-layered structure including a first polyimide layer, a second polyimide layer and an interlayer inorganic layer between the first and second polyimide layers.

A first buffer layer 104 is formed on the substrate 102. The first buffer layer 104 can be formed of an inorganic insulating material, e.g., silicon oxide (SiO2) or silicon nitride (SiNx). In addition, the first buffer layer 104 can have a single-layered structure or a multi-layered structure.

A first light shielding pattern 106 can be disposed on the first buffer layer 104. The light through the substrate 102 can be blocked by the first light shielding pattern 106. For example, the first light shielding pattern 106 can be formed of a metallic material, e.g., molybdenum (Mo), aluminum (Al), chromium (Cr), gold (Au), titanium (Ti), nickel (Ni), neodymium (Nd), and copper (Cu) or their alloys. In addition, the first light shielding pattern 106 can have a single-layered structure or a multi-layered structure.

A second buffer layer 108 covering the first light shielding pattern 106 can be disposed over the substrate 102. For example, the second buffer layer 108 can be formed of the above inorganic insulating material and can have a single-layered structure or a multi-layered structure.

A first semiconductor layer 110 corresponding to the first light shielding pattern 106 can be disposed on the second buffer layer 108. The first semiconductor layer 110 can include one of a polycrystalline semiconductor material, an amorphous semiconductor material and an oxide semiconductor material. When the first light shielding pattern 106 and the first buffer layer 104 are omitted, the first semiconductor layer 110 can be disposed directly on the substrate 102.

In an aspect of the present disclosure, the first semiconductor layer 110 can include the polycrystalline semiconductor material, e.g., polycrystalline silicon. The first semiconductor layer 110 can include a first channel region, a first source region at one side of the first channel region and a first drain region at the other side of the first channel region. An impurity can be doped into the first source and drain regions.

A first gate insulating layer 112 covering the first semiconductor layer 110 can be disposed on or over the second buffer layer 108. For example, the first gate insulating layer 112 can include an inorganic insulating material, e.g., silicon oxide or silicon nitride. The first gate insulating layer 112 can have a single-layered structure or a multi-layered structure.

A first gate electrode 114 corresponding to the first channel region of the first semiconductor layer 110 can be disposed on the first gate insulating layer 112. Also, a first capacitance electrode spaced apart from the first gate electrode 114 can be disposed on the first gate insulating layer 112.

The first gate electrode 114 and the first capacitance electrode can be disposed at the same layer and can be formed of the same material. For example, each of the first gate electrode 114 and the first capacitance electrode can include the above metallic material. In addition, each of the first gate electrode 114 and the first capacitance electrode can have a single-layered structure or a multi-layered structure.

A first interlayer insulating layer 116 covering the first gate electrode 114 can be disposed on or over the first gate insulating layer 112. The first interlayer insulating layer 116 can be formed of the above inorganic insulating material. In addition, the first interlayer insulating layer 116 can have a single-layered structure or a multi-layered structure.

A third buffer layer 118 can be disposed on the first interlayer insulating layer 116, and a second light shielding pattern 120 can be disposed on the third buffer layer 118. The light through the substrate 102 can be blocked by the second light shielding pattern 120.

A second capacitance electrode corresponding to the first capacitance electrode can be disposed on the third buffer layer 118. The second capacitance electrode can be spaced apart from the second light shielding pattern 120.

The second light shielding pattern 120 and the second capacitance electrode can be disposed at the same layer and can be formed of the same material. For example, each of the second light shielding pattern 120 and the second capacitance electrode can be formed of the above metallic material. In addition, each of the second light shielding pattern 120 and the second capacitance electrode can have a single-layered structure or a multi-layered structure.

A second interlayer insulating layer 122 covering the second light shielding pattern 120 and the second capacitance electrode can be disposed on or over the third buffer layer 118. For example, the second interlayer insulating layer 122 can be formed of the above inorganic insulating material or an organic insulating material, e.g., photo-acryl or benzocyclobutene. In addition, the second interlayer insulating layer 122 can have a single-layered structure or a multi-layered structure.

A second semiconductor layer 124 corresponding to the second light shielding pattern 120 can be disposed on the second interlayer insulating layer 122. The second semiconductor layer 124 can include one of a polycrystalline semiconductor material, an amorphous semiconductor material and an oxide semiconductor material.

In an aspect of the present disclosure, the second semiconductor layer 124 can include the oxide semiconductor material, e.g., indium-gallium-zinc oxide (IGZO), zinc oxide(ZnO), tin oxide(SnO2), copper oxide(Cu2O), nickel oxide(NiO), ndium-tin-zinc oxide (ITZO) or indium-aluminum-zinc oxide (IAZO). The second semiconductor layer 124 can include a second channel region, a second source region at one side of the second channel region and a second drain region at the other side of the second channel region. An impurity can be doped into the second source and drain regions.

A second gate insulating layer 126 covering the second semiconductor layer 124 can be disposed on or over the second interlayer insulating layer 122. For example, the second gate insulating layer 126 can include the above inorganic insulating material. The second gate insulating layer 126 can have a single-layered structure or a multi-layered structure.

A second gate electrode 128 corresponding to the second channel region of the second semiconductor layer 124 can be disposed on the second gate insulating layer 126. For example, the second gate electrode 128 can include the above metallic material. The second gate electrode 128 can have a single-layered structure or a multi-layered structure.

A third interlayer insulating layer 130 covering the second gate electrode 128 can be disposed on or over the second gate insulating layer 126. The third interlayer insulating layer 130 can be formed of the above inorganic insulating material. In addition, the third interlayer insulating layer 130 can have a single-layered structure or a multi-layered structure.

On the third interlayer insulating layer 130, a first source electrode 132, the first drain electrode 134, the second source electrode 136 and the second drain electrode 138, which are spaced apart from each other, can be disposed.

The first source electrode 132 and the first drain electrode 134 can be respectively connected to the first source and drain regions of the first semiconductor layer 110 through contact holes formed through the third interlayer insulating layer 130, the second gate insulating layer 126, the second interlayer insulating layer 122, the third buffer layer 118, the first interlayer insulating layer 116 and the first gate insulating layer 112. In addition, the first drain electrode 134 can be connected to the first capacitance electrode.

The second source electrode 136 and the second drain electrode 138 can be respectively connected to the second source and drain regions of the second semiconductor layer 124 through contact holes formed through the third interlayer insulating layer 130 and the second gate insulating layer 126. In addition, the second drain electrode 138 can be connected to the second capacitance electrode.

The first source electrode 132, the first drain electrode 134, the second source electrode 136 and the second drain electrode 138 can be disposed at the same layer and can be formed of the same material. For example, each of the first source electrode 132, the first drain electrode 134, the second source electrode 136 and the second drain electrode 138 can include the above metallic material and can have a single-layered structure or a multi-layered structure.

The first semiconductor layer 110, the first gate electrode 114, the first source electrode 132 and the first drain electrode 134 constitute a first thin film transistor (TFT) T1, and the second semiconductor layer 124, the second gate electrode 128, the second source electrode 136 and the second drain electrode 138 constitute a second TFT T2. For example, the first TFT T1 can be a switching TFT, and the second TFT T2 can be a driving TFT. In addition, the first and second capacitance electrodes can constitute a storage capacitor.

The light emitting diode display device 100 includes the first and second TFTs T1 and T2, each of the first semiconductor layer 110 of the first TFT T1 and the second semiconductor layer 124 of the second TFT T2 can include a polycrystalline semiconductor material, an amorphous semiconductor material or an oxide semiconductor material. In addition, at least one of the first semiconductor layer 110 of the first TFT T1 and the second semiconductor layer 124 of the second TFT T2 can include the oxide semiconductor material. In an aspect of the present disclosure, the first semiconductor layer 110 of the first TFT T1 can include the polycrystalline semiconductor material, e.g., polycrystalline silicon, and the second semiconductor layer 124 of the second TFT T2 can include the oxide semiconductor material.

In the TFT T1 in FIG. 2, the first gate electrode 114, the first source electrode 132, and the first drain electrode 134 are positioned over the first semiconductor layer 110, and in the TFT T2, the second gate electrode 128, the second source electrode 136, and the second drain electrode 138 are positioned over the second semiconductor layer 124. Namely, each of the first and second TFTs T1 and T2 has a coplanar structure. Alternatively, in each of the first and second TFTs T1 and T2, the gate electrode can be positioned under the semiconductor layer, and the source and drain electrodes can be positioned over the semiconductor layer such that each of the first and second TFTs T1 and T2 can have an inverted staggered structure.

A planarization layer 140 covering the first source electrode 132, the first drain electrode 134, the second source electrode 136 and the second drain electrode 138 can be disposed on or over the third interlayer insulating layer 130. The planarization layer 140 can be formed of an organic material, e.g., photo-acryl or benzocyclobutene (BCB).

The planarization layer 140 can include a first planarization layer 141 on the first source electrode 132, the first drain electrode 134, the second source electrode 136 and the second drain electrode 138 and second planarization layer 143 on the first planarization layer 141. The first and second planarization layers 141 and 143 can be formed of the same material or different materials.

A connection electrode 144 corresponding to the second drain electrode 138 can be disposed on the planarization layer 141. the connection electrode 144 can be connected to the second drain electrode through a contact hole in the first planarization layer 141. For example, the connection electrode 144 can include the above metallic material and can have a single-layered structure or a multi-layered structure.

An anode 160a corresponding to the emission area EA is disposed on the second planarization layer 143. The anode 160a can correspond to the connection electrode 144 and can be connected to the connection electrode 144 through a contact hole in the second planarization layer 143.

The anode 160a is separately formed in each pixel region P. The anode 160a can include a transparent layer, which includes a conductive material, e.g., a transparent conductive oxide (TCO), having a relatively high work function, and a reflection layer.

For example, the transparent layer can be formed of indium-tin-oxide (ITO), indium-zinc-oxide (IZO), indium-tin-zinc-oxide (ITZO), tin oxide (SnO), zinc oxide (ZnO), indium-copper-oxide (ICO) or aluminum-zinc-oxide (Al: ZnO, AZO), and the reflection layer can be formed of silver (Ag), an alloy of one of palladium (Pd), Cu, In and Nd and with Ag, or aluminum-palladium-copper (APC) alloy. For example, the anode 160a can have a double-layered structure of Ag/ITO or APC/ITO or a triple-layered structure of ITO/Ag/ITO or ITO/APC/ITO.

In addition, a bank 154 is formed on the second planarization layer 143 and corresponds to a boundary of the pixel region P. Namely, the bank 154 is disposed at the non-emission area NEA. The bank 154 covers an edge of the anode 160a and includes an opening to expose a center of the anode 160a. The bank 154 can be formed of an inorganic insulating material, e.g., silicon oxide or silicon nitride, or an organic insulating material, e.g., photo-acryl, BCB or polyimide. The bank 154 can have a single-layered structure or a multi-layered structure.

An emitting layer 160b covering the anode 160a and the bank 154 is disposed. The emitting layer 160b contacts the anode 160a in the opening of the bank 154.

For example, the emitting layer 160b can include an organic emitting material or an inorganic emitting material. Namely, the display device 100 of the present disclosure can be an organic light emitting display device or an inorganic light emitting display device.

A cathode 160c can be disposed on the emitting layer 160b. The cathode 160c can be disposed on an entire surface of the display area DA. The cathode 160c can include at least one of ITO, IZO, Al, Ag, Cu, Pb, Mg, Mo, Ti and their alloys. In addition, the cathode 160c can have a single-layered structure or a multi-layered structure. The cathode 160c can have a thin profile to be a transparent electrode or a semi-transparent electrode.

The anode 160a, the emitting layer 160b and the cathode 160c constitute a light emitting diode D. The light emitting diode D can provide red, green and blue emission in each of the red, green and blue pixel regions, respectively.

In the display device 100, the light from the emitting layer 160b is displayed through the cathode 160c. Namely, the display device 100 of the present disclosure is a top-emission display device.

An encapsulation layer (or an encapsulation film) 162 is formed on the cathode 160c to prevent penetration of moisture into the light emitting diode D. The encapsulation layer 162 includes a first inorganic insulating layer 162a, an organic insulating layer 162b and a second inorganic insulating layer 162c sequentially stacked, but it is not limited thereto.

For example, each of the first and second inorganic insulating layers 162a and 162c can be formed of an inorganic insulating material, e.g., silico oxide or silicon nitride, and the organic insulating material 162b can be formed of an organic insulating material, e.g., acryl resin, epoxy resin, phenolic resin, polyamide resin or polyimide resin.

Also, a touch electrode layer can be disposed on the encapsulation layer 162. In addition, a color filter layer can be disposed on the encapsulation layer 162.

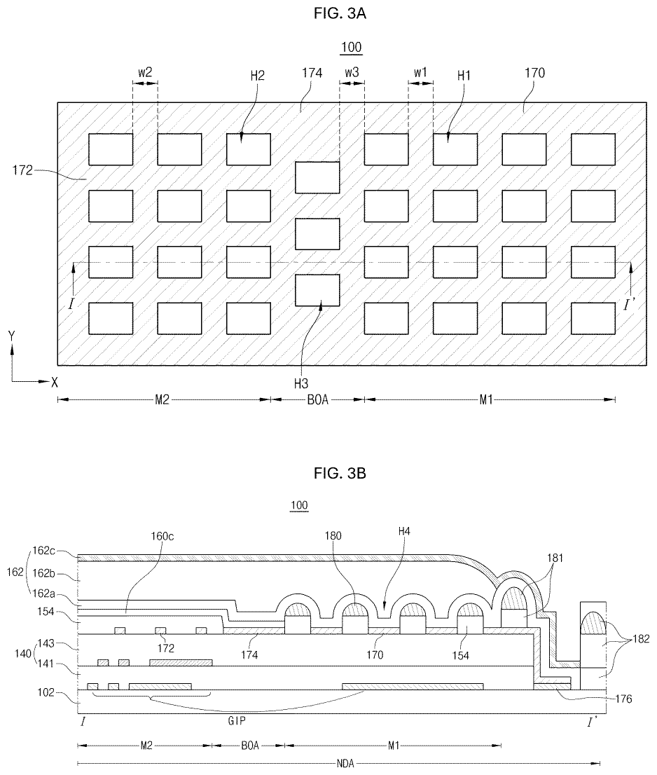

FIG. 3A is a schematic plane view illustrating a display device in a non-display area according to a first embodiment of the present disclosure. FIG. 3A is an enlarged view of an “A” part in FIG. 1.

As shown in FIG. 3A, in the non-display area NDA of the display device 100, a first mesh region M1, a second mesh region M2 between the first mesh region M1 and the display area DA (of FIG. 1) and a bank open area BOA between the first and second mesh areas M1 and M2. Namely, along a first direction X, the second mesh area M2, the bank open area BOA and first mesh area M1 are arranged.

A conductive mesh pattern (e.g., a conductive mesh layer) is disposed in each of the first and second mesh areas M1 and M2 and the bank open area BOA. The conductive mesh pattern includes a first mesh pattern 170 in the first mesh area M1, a second mesh pattern 172 in the second mesh area M2 and a third mesh pattern 174 in the bank open area BOA. The first mesh pattern 170 extends from one end of the third mesh pattern 174 so that the first and third mesh patterns 170 and 174 are electrically connected to each other. The second mesh pattern 172 extends from the other end of the third mesh pattern 174 so that the first to third mesh patterns 170, 172 and 174 are electrically connected to each other.

The conductive mesh pattern includes at least one hole exposing a surface of the planarization layer 140 for out-gassing of the planarization layer 140. For example, the conductive mesh pattern can include a plurality of holes over top of the planarization layer 140 to allow for gases to escape from the planarization layer 140. The holes in the conductive mesh pattern can have a rectangular shape in a plan view, but embodiments are not limited thereto. For example, according to other embodiments, the holes in the conductive mesh pattern can have a circular shape, an oval shape, square shape, polygon shape, triangular shape, or a shape with rounded corners, etc.

The first conductive mesh pattern 170 can be disposed at the same layer and formed of the same material as the anode 160a of the light emitting diode D. For example, the first mesh pattern 170 can include the transparent layer and the reflection layer.

The first conductive mesh pattern 170 in the first mesh area M1 is formed with a first width w1 and includes a first hole H1. The first holes H1 are arranged to be spaced apart from each other along the first direction X and the second direction Y, which can cross the first direction X. For example, the second direction Y can be perpendicular to the first direction X.

The second conductive mesh pattern 172 in the second mesh area M2 is formed with a second width w2 and includes a second hole H2. The second holes H2 are arranged to be spaced apart from each other along the first direction X and the second direction Y.

The third conductive mesh pattern 174 in the bank open area BOA is formed with a third width w3 and includes a third hole H3. The third holes H3 are arranged to be spaced apart from each other along the second direction Y. In an aspect of the present disclosure, the third holes H3 are arranged to be spaced apart from each other along the first direction X and the second direction Y.

The first width w1 of the first conductive mesh pattern 170 can be equal to the second width w2 of the second conductive mesh pattern 172 (e.g., w1=w2). In addition, an area of the first hole H1 can be equal to an area of the second hole H2.

Alternatively, the first width w1 of the first conductive mesh pattern 170 can be smaller than the second width w2 of the second conductive mesh pattern 172 (e.g., w1<w2) so that an area of the first hole H1 can be larger than that of the second hole H2. For efficient out-gassing in edge of the non-display area, the first conductive mesh pattern 170 can have a width smaller than the second conductive mesh pattern 172 (e.g., w1<w2), and the first hole H1 can have an area larger than the second hole H2. For example, the second holes H2 can be larger and spaced closer together than the first holes H1, but embodiments are not limited thereto.

A third width w3 of the third conductive mesh pattern 174 can be equal to each of the first and second widths w1 and w2 (e.g., w3=w1=w2). In addition, an area of the third hole H3 can be equal to an area of each of the first and second holes H1 and H2, but embodiments are not limited thereto.

FIG. 3B is a schematic cross-sectional taken along the line I-I′ of FIG. 3A. Elements between the substrate 102 and the first planarization layer 141 are omitted for convenience of explanation.

Referring to FIGS. 3A and 3B, the planarization layer 140 including the first planarization layer 141 and the second planarization layer 143 is disposed over the substrate 102. In addition, a gate driving unit, e.g., a gate-in-panel type gate driving unit, including at least one electrode and at least one signal line can be disposed in the first planarization layer 141 and the second planarization layer 143.

Moreover, a low potential voltage line 176 can be disposed over the substrate 102.

The conductive mesh pattern including the first, second and third conductive mesh patterns 170, 172 and 174 are disposed on the second planarization layer 143. The first conductive mesh pattern 170 is positioned in the first mesh area M1, the second conductive mesh pattern 172 is positioned in the second mesh area M2, and the third conductive mesh pattern 174 is positioned in the bank open area BOA.

Namely, the first conductive mesh pattern 170 can be positioned between the display area DA (of FIG. 1) and the low potential voltage line 176, and the second conductive mesh pattern 172 can be positioned between the display area DA and the first conductive mesh pattern 170, and the third conductive mesh pattern 174 can be positioned between the first and second conductive mesh patterns 170 and 172.

The first conductive mesh pattern 170 extends along a side surface of the first and second planarization layers 141 and 143 and is connected to the low potential voltage line 176.

The first, second and third conductive mesh patterns 170, 172 and 174 respectively include the first, second and third holes H1, H2 and H3 to expose a portion of the second planarization layer 143 in the first mesh area M1, the second mesh area M2 and the bank open area BOA. Namely, the first, second and third holes H1, H2 and H3 serve as an out-gassing path for the planarization layer 140.

The bank 154 is disposed in the first and second mesh areas M1 and M2 to cover the first and second conductive mesh patterns 170 and 172. The bank 154 in the first mesh area M1 is disposed to correspond to the first hole H1 and exposes the first conductive mesh pattern 170. Namely, the bank 154 in the first mesh area M1 includes a fourth hole H4 exposing the first conductive mesh pattern 170. The bank 154 in the second mesh area M2 can completely cover the second conductive mesh pattern 172. In addition, the bank 154 is not presented in the bank open area BOA so that the third conductive mesh pattern 174 is exposed.

A spacer 180 is disposed on or between portions of the first mesh pattern M1 to correspond to the bank 154. The spacer 180 can have the same thickness as the bank 154, but embodiments are not limited thereto and the spacer 180 can have a different thickness than the bank 154. For example, the spacer 180 can be formed of an inorganic insulating material, e.g., silicon oxide or silicon nitride, or an organic insulating material, e.g., photo-acryl, BCB or polyimide.

The spacer 180 is positioned between the first conductive mesh patterns 170 and corresponds to the first hole H1. The spacer 180 can have an area equal to or smaller than an area of the first hole H1.

The cathode 160c of the light emitting diode D extends into the second mesh area M2 and the bank open area BOA. Namely, the extending portion of the cathode 160c covers the bank 154 in the second mesh area M2 and contacts the third conductive mesh pattern 174 in the bank open area BOA. The cathode 160c is connected to the low potential voltage line 176 through the third conductive mesh pattern 174 and the first conductive mesh pattern 170 so that the low potential voltage can be applied to the cathode 160c. A portion, which contacts the third conductive mesh pattern 174, of the cathode 160c can be referred to as a contact electrode.

A first dam 181 can be disposed at an outer side of the first mesh area M1. The first dam 181 can include a spacer portion on a portion of the bank. In addition, a second dam 182 can be disposed at an outer side of the first dam 181. For example, the low potential voltage line 176 can be positioned between the first and second dams 181 and 182.

When the organic layer 162b of the encapsulation layer 162 is formed by a solution process, the overflow of an organic material solution to an edge of the substrate 102 can be prevented by the first and second dams 180 and 182.

The encapsulation layer 162 extends from the display area DA into the first and second mesh areas M1 and M2 and the bank open area BOA to be disposed in the first and second mesh areas M1 and M2 and the bank open area BOA. Namely, the encapsulation layer 162 covers the spacer 181 and the first conductive mesh pattern 170 exposed between spacers 180 in the first mesh area M1, the cathode 160c in the second mesh area M2 and the contact electrode as an end of the cathode 160c in the bank open area BOA.

As described above, the encapsulation layer 162 includes the first inorganic layer 162a, the organic layer 162b and the second inorganic layer 162c, and each of the first and second inorganic layers 162a and 162c can cover the first conductive mesh pattern 170, which contacts the low potential voltage line 176, beyond the first dam 180. The organic layer 162b is disposed in an area surrounded by the first dam 181, and a side of the organic layer 162b can be covered by the first and second inorganic layers 162a and 162c. For example, an edge of the organic layer 162b can be sealed by the first and second inorganic layers 162a and 162c.

The bank 154 of the display device 100 can be formed by a deposition process using a deposition mask, and an edge of the substrate 102, e.g., an end portion of the first mesh area M1, can be covered by the deposition mask so that the bank 154 can be formed with a relatively small thickness at the end portion of the first mesh area M1. In this situation, the static electricity may be generated between the deposition mask and the first conductive mesh pattern 170 in the first mesh area M1 so that damage to the display device 100 and/or the deposition mask can be caused. For example, a spark may be generated between the deposition mask and the first conductive mesh pattern 170 in the first mesh area M1 which passes through the thin portions of the bank 154, which can result in a burnt or damaged area.

However, in the display device 100 of the present disclosure, since the spacer 180 is disposed in correspondence to the bank 154 in the first mesh area M1, the static electricity between the deposition mask and the first conductive mesh pattern 170 can be prevented or minimized. For example, the spacer 180 can be made of insulating material and its configuration can allow for more insulating material to be spaced between the deposition mask and the first conductive mesh pattern 170, in order to prevent or protect against electrical static discharge.

In addition, when a width of the first conductive mesh pattern 170 is decreased to provide larger holes that are spaced closer together for efficient out-gassing in edge of the non-display area, the resistance of the first conductive mesh pattern 170 is increased so that a risk for potential damage, e.g., a burnt problem, on the first conductive mesh pattern 170 may be increased. However, in the display device 100 according to an embodiment of the present disclosure, since the spacer 180 is disposed in correspondence to the bank 154 in the first mesh area M1, the damage, e.g., a burnt problem, on the first conductive mesh pattern 170 can be prevented or minimized.

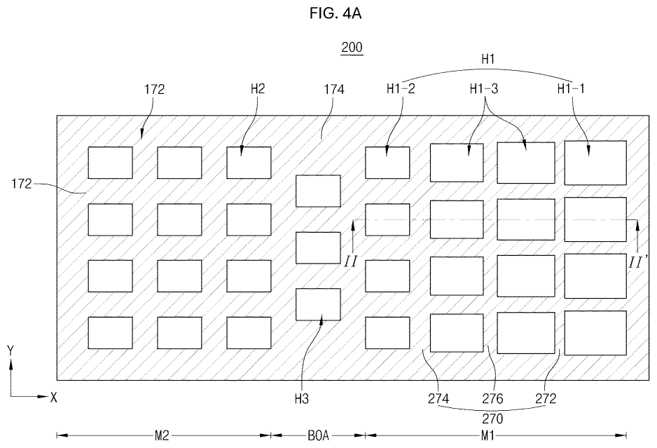

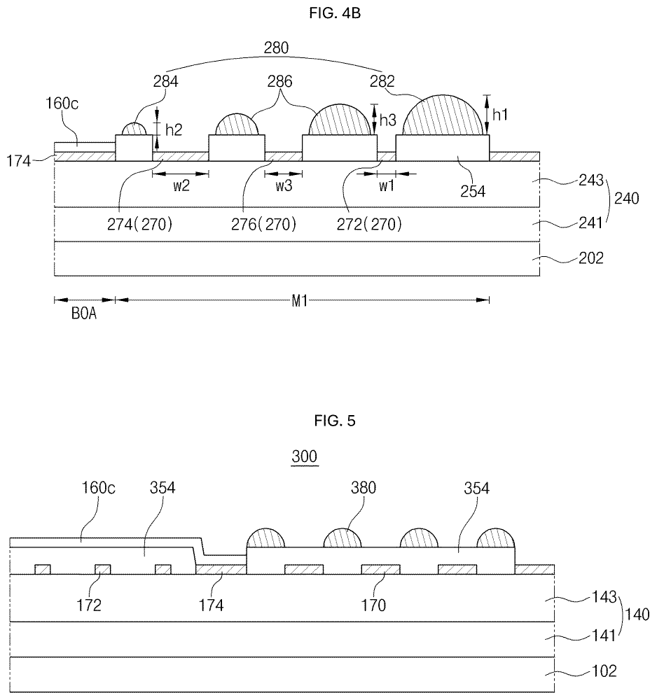

FIG. 4A is a schematic plane view illustrating a display device in a non-display area according to a second embodiment of the present disclosure. FIG. 4A is an enlarged view of an “A” part in FIG. 1.

As shown in FIG. 4A, in the non-display area NDA of the display device 200, a first mesh region M1, a second mesh region M2 between the first mesh region M1 and the display area DA (of FIG. 1) and a bank open area BOA between the first and second mesh areas M1 and M2.

A first mesh pattern 270 is disposed in the first mesh area M1, a second mesh pattern 272 is disposed in the second mesh area M2, and a third mesh pattern 274 is disposed in the bank open area BOA.

The display device 200 according to the second embodiment of the present disclosure has a difference in a configuration of the first mesh area M1 from the display device 100 according to the first embodiment of the present disclosure.

In the display device 200 according to the second embodiment of the present disclosure, the first conductive mesh pattern 270 includes a first hole H1 including a first sub-hole H1-1, a second sub-hole H1-2 between the first sub-hole H1-1 and the bank open area BOA. An area of the first sub-hole H1-1 can be greater than that of the second sub-hole H1-2 so that the out-gassing from the planarization layer 140 (of FIG. 3B) at an edge of the display device 200 can be efficiently generated.

In addition, the first hole H1 of the first conductive mesh pattern 270 can further include a third sub-hole H1-3 between the first and second sub-holes H1-1 and H1-2. An area of the third sub-hole H1-3 can be smaller than that of the first sub-hole H1-1 and greater than that of the second sub-hole H1-2.

In an aspect of the present disclosure, the area of the second sub-hole H1-2 can be equal to a second hole H2 of the second conductive mesh pattern 172 in the second mesh area M2.

Namely, the first conductive mesh pattern 270 in the first mesh area M1 includes a first sub-pattern 272 and a second sub-pattern 274 between the first sub-pattern 272 and the bank open area BOA. A width of the first sub-pattern 272 can be smaller than that of the second sub-pattern 274. In addition, the first conductive mesh pattern 270 can further include a third sub-pattern 276 between the first and second sub-patterns 272 and 274. A width of the third sub-pattern 276 can be greater than that of the first sub-pattern 272 and smaller than that of the second sub-pattern 274.

FIG. 4B is a schematic cross-sectional taken along the line II-II′ of FIG. 4A. Elements between the substrate 202 and the first planarization layer 241 and the gate driving unit are omitted for convenience of explanation.

Referring to FIGS. 4A and 4B, the planarization layer 240 including the first planarization layer 241 and the second planarization layer 243 is disposed over the substrate 102.

The first conductive mesh pattern 270 is disposed in the first mesh pattern M1 and on the second planarization layer 243.

The first conductive mesh pattern 270 can include the first sub-pattern 272, the second sub-pattern 274 between the first sub-pattern 272 and the bank open area BOA and the third sub-pattern 276 between the first and second sub-patterns 272 and 274.

The first sub-pattern 272 can have a first width w1, and the second sub-pattern 274 can have a second width w2 being large than the first width w1. The third sub-pattern 276 can have a third width w3 being larger than the first width w1 and smaller than the second width w2 (e.g., w2>w3>w1).

The first conductive mesh pattern 270 can include the first sub-hole H1-1, the second sub-hole H1-2 between the first sub-hole H1-1 and the bank open area BOA and the third sub-hole H1-3 between the first and second sub-holes H1-1 and H1-2. An area of the third sub-hole H1-3 can be smaller than an area of the first sub-hole H1-1 and larger than an area of the second sub-hole H1-2 (e.g., area of H1-1>area of H1-3>area of H1-2).

In the first mesh area M1, a bank 254 is disposed to correspond to the first hole H1 of the first conductive mesh pattern 270. Namely, the bank 254 corresponds to a space between the first conductive mesh patterns 270 and exposes the first conductive mesh pattern 270.

In the first mesh area M1, the bank 254 can include a first bank pattern, a second bank pattern between the first bank pattern and the bank open area BOA and a third bank pattern between the first and second bank patterns. In this situation, a width of the third bank pattern can be smaller than a width of the first bank pattern and larger than a width of the second bank pattern.

In the first mesh area M1, a spacer 280 is disposed on the bank 254. For example, the spacer 280 can be formed of an inorganic insulating material, e.g., silicon oxide or silicon nitride, or an organic insulating material, e.g., photo-acryl, BCB or polyimide.

The spacer 280 corresponds to the first hole H1. Namely, the spacer 280 can include a first spacer 282 corresponding to the first sub-hole H1-1, a second spacer 284 corresponding to the second sub-hole H1-2 and a third spacer 286 corresponding to the third sub-hole H1-3. The first, second and third spacers 282, 284 and 286 can respectively correspond to the first, second and third sub-holes H1-1, H1-2 and H1-3 and be spaced apart from each other.

The first spacer 282 can have a first height h1, and the second spacer 284 can have a second height h2 smaller than the first height h1. The third spacer 286 can have a third height h3 smaller than the first height h1 and greater than the second height h2 (e.g., h1>h3>h2).

In an aspect of the present disclosure, a height of the spacer 280 can be gradually increased along the first direction X closer to the outer edge of the substrate 202 (e.g., the spacers can gradually get wider and taller as the distance away from the display area increases to increase insulation protection).

Since the first width w1 of the first sub-pattern 272 is smaller than the second width w2 of the second sub-pattern 274, the first sub-pattern 272 has a relatively high resistance so that there can be a damage, e.g., the risk potential of a burnt problem, on the first bank pattern 254 being adjacent to the first sub-pattern 272 can increase. However, in the display device 200 of the present disclosure, the first height h1 of the first spacer 254 on the first bank pattern 254 is relatively large, the damage on the first bank pattern 254 can be sufficiently compensated. In other words, more insulation material can be disposed over the areas of the conductive mesh pattern that have higher resistance due to the configuration of the spacers, which can improve protection for these areas against static electrical discharge.

In addition, a static electricity between the deposition mask and the first conductive mesh pattern 270 can be prevented by the spacer 280 in the first mesh area M1.

FIG. 5 is a schematic cross-sectional view illustrating a display device in a non-display area according to a third embodiment of the present disclosure. FIG. 5 is a schematic cross-sectional taken along the line I-I′ of FIG. 3A. Elements between the substrate 102 and the first planarization layer 141, the gate driving unit, the first and second dams and the low potential voltage line are omitted for convenience of explanation.

Referring to FIGS. 3A and 5, the planarization layer 140 including the first planarization layer 141 and the second planarization layer 143 is disposed over the substrate 102.

The conductive mesh pattern including the first, second and third conductive mesh patterns 170, 172 and 174 are disposed on the second planarization layer 143. The first conductive mesh pattern 170 is positioned in the first mesh area M1, the second conductive mesh pattern 172 is positioned in the second mesh area M2, and the third conductive mesh pattern 174 is positioned in the bank open area BOA (e.g., 174 is between 172 and 170).

The first, second and third conductive mesh patterns 170, 172 and 174 respectively include first, second and third holes H1, H2 and H3 so that a portion of the second planarization layer 143 in the first mesh pattern M1, the second mesh pattern M2 and the bank open area BOA is exposed. Namely, the first, second and third holes H1, H2 and H3 serve as an out-gassing path for the planarization layer 140.

The bank 354 is disposed in the first and second mesh areas M1 and M2 to cover the first and second conductive mesh patterns 170 and 172. The bank 354 is provided on an entire surface of the first mesh area M1 to cover the first conductive mesh pattern 170. The bank 354 is provided on an entire surface of the second mesh area M2 to cover the second conductive mesh pattern 172. The bank 354 is not provided in the bank open area BOA so that the third conductive mesh pattern 174 is not covered with the bank 354 and exposed by the bank 354.

A spacer 380 is disposed in the first mesh pattern M1 to correspond to the bank 354. The spacer 380 can have the same thickness as the bank 354, but embodiments are not limited thereto and different thicknesses can be provided. For example, the spacer 380 can be formed of an inorganic insulating material, e.g., silicon oxide or silicon nitride, or an organic insulating material, e.g., photo-acryl, BCB or polyimide.

The spacer 380 is positioned between the first conductive mesh patterns 170 and corresponds to the first hole H1. The spacer 380 can have an area equal to or smaller than an area of the first hole H1.

The cathode 160c of the light emitting diode D extends into the second mesh area M2 and the bank open area BOA. Namely, the extending portion of the cathode 160c covers the bank 354 in the second mesh area M2 and contacts the third conductive mesh pattern 174 in the bank open area BOA. The cathode 160c is connected to the low potential voltage line 176 (of FIG. 3B) through the third conductive mesh pattern 174 and the first conductive mesh pattern 170 so that the low potential voltage can be applied to the cathode 160c. A portion, which contacts the third conductive mesh pattern 174, of the cathode 160c can be referred to as a contact electrode.

In FIG. 5, the first conductive mesh pattern 170 has the same spacing as the second conductive mesh pattern 172. Accordingly, the first hole H1 of the first conductive mesh pattern 170 has the same area as the second hole H2 of the second conductive mesh pattern 172. Alternatively, the first conductive mesh pattern 170 can have a width being smaller than the second conductive mesh pattern 172, and the first hole H1 can have an area greater than the second hole H2.

In FIG. 5, the spacer 380 has the same, e.g., constant, thickness. Alternatively, as illustrated in FIGS. 4A and 4B, the spacer 380 can include a first spacer and a second spacer between the first spacer and the bank open area BOA, and a height of the first spacer can be greater than a height of the second spacer. In addition, the spacer 380 can further include a third spacer between the first and second spacers, and a height of the third spacer can be smaller than a height of the first spacer and greater than a height of the second spacer.

In FIG. 5, the first conductive mesh pattern 170 has the same, e.g., constant, width, and the first hole H1 has the same, e.g., constant, area. Alternatively, as illustrated in FIGS. 4A and 4B, the first conductive mesh pattern 170 can include a first sub-pattern and a second sub-pattern between the first sub-pattern and the bank open area BOA, and the first hole H1 can include a first sub-hole and a second sub-hole between the first sub-hole and the bank open area BOA. In this situation, a width of the first sub-pattern can be smaller than a width of the second sub-pattern, and an area of the first sub-hole can be greater than an area of the second sub-hole. In addition, the first conductive mesh pattern 170 can further include a third sub-pattern between the first and second sub-patterns, and the first hole H1 can further include a third sub-hole between the first and second sub-holes. In this situation, a width of the third sub-pattern can be greater than a width of the first sub-pattern and smaller than a width of the second sub-pattern, and an area of the third sub-hole can be smaller than an area of the first sub-hole and greater than that of the second sub-hole.

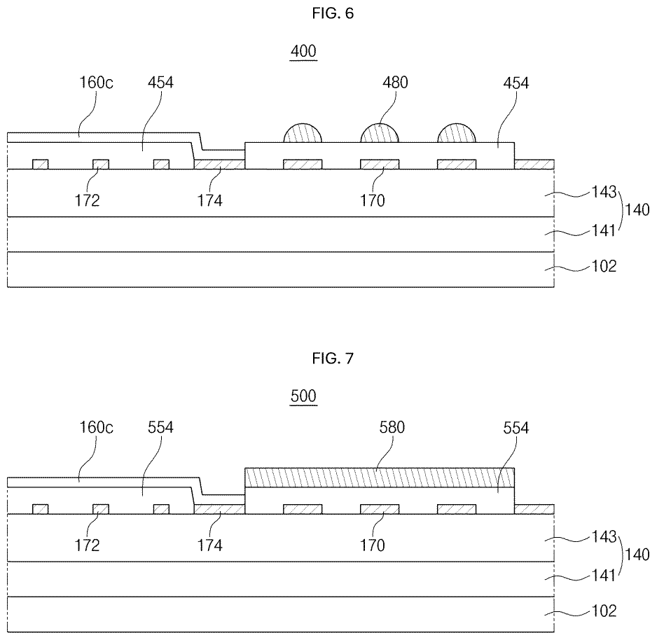

FIG. 6 is a schematic cross-sectional view illustrating a display device in a non-display area according to a fourth embodiment of the present disclosure. FIG. 6 is a schematic cross-sectional taken along the line I-I′ of FIG. 3A. Elements between the substrate 102 and the first planarization layer 141, the gate driving unit, the first and second dams and the low potential voltage line are omitted for convenience of explanation.

Referring to FIGS. 3A and 6, the planarization layer 140 including the first planarization layer 141 and the second planarization layer 143 is disposed over the substrate 102.

The conductive mesh pattern including the first, second and third conductive mesh patterns 170, 172 and 174 are disposed on the second planarization layer 143. The first conductive mesh pattern 170 is positioned in the first mesh area M1, the second conductive mesh pattern 172 is positioned in the second mesh area M2, and the third conductive mesh pattern 174 is positioned in the bank open area BOA.

The first, second and third conductive mesh patterns 170, 172 and 174 respectively include first, second and third holes H1, H2 and H3 so that a portion of the second planarization layer 143 in the first mesh pattern M1, the second mesh pattern M2 and the bank open area BOA is exposed. Namely, the first, second and third holes H1, H2 and H3 serve as an out-gassing path for the planarization layer 140.

The bank 454 is disposed in the first and second mesh areas M1 and M2 to cover the first and second conductive mesh patterns 170 and 172. The bank 454 is provided on an entire surface of the first mesh area M1 to cover the first conductive mesh pattern 170. The bank 454 is provided on an entire surface of the second mesh area M2 to cover the second conductive mesh pattern 172. The bank 454 is not provided in the bank open area BOA so that the third conductive mesh pattern 174 is not covered by the bank 454 and exposed.

A spacer 480 is disposed in the first mesh pattern M1 to correspond to the bank 454. The spacer 480 can have the same thickness as the bank 454, but embodiments are not limited thereto and different thicknesses can be provided. For example, the spacer 480 can be formed of an inorganic insulating material, e.g., silicon oxide or silicon nitride, or an organic insulating material, e.g., photo-acryl, BCB or polyimide.

The spacer 480 is disposed to correspond to the first conductive mesh pattern 170 (e.g., 480 can overlap with 170). The spacer 480 can have an area equal to or smaller than an area of the first conductive mesh pattern 170. A space between the spacers 480 can correspond to the first hole H1 of the first conductive mesh pattern 170.

The cathode 160c of the light emitting diode D extends into the second mesh area M2 and the bank open area BOA. Namely, the extending portion of the cathode 160c covers the bank 454 in the second mesh area M2 and contacts the third conductive mesh pattern 174 in the bank open area BOA. The cathode 160c is connected to the low potential voltage line 176 (of FIG. 3B) through the third conductive mesh pattern 174 and the first conductive mesh pattern 170 so that the low potential voltage can be applied to the cathode 160c. A portion, which contacts the third conductive mesh pattern 174, of the cathode 160c can be referred to as a contact electrode.

In FIG. 6, the first conductive mesh pattern 170 has the same spacing as the second conductive mesh pattern 172. Accordingly, the first hole H1 of the first conductive mesh pattern 170 has the same area as the second hole H2 of the second conductive mesh pattern 172. Alternatively, the first conductive mesh pattern 170 can have a width or spacing that is smaller than the second conductive mesh pattern 172, and the first hole H1 can have an area greater than the second hole H2.

In FIG. 6, the spacer 480 has the same, e.g., constant, thickness. Alternatively, as illustrated in FIGS. 4A and 4B, the spacer 480 can include a first spacer and a second spacer between the first spacer and the bank open area BOA, and a height of the first spacer can be greater than that of the second spacer. In addition, the spacer 480 can further include a third spacer between the first and second spacers, and a height of the third spacer can be smaller than a height of the first spacer and greater than a height of the second spacer.

In FIG. 6, the first conductive mesh pattern 170 has the same, e.g., constant, width, and the first hole H1 has the same, e.g., constant, area. Alternatively, as illustrated in FIGS. 4A and 4B, the first conductive mesh pattern 170 can include a first sub-pattern and a second sub-pattern between the first sub-pattern and the bank open area BOA, and the first hole H1 can include a first sub-hole and a second sub-hole between the first sub-hole and the bank open area BOA. In this situation, a width of the first sub-pattern can be smaller than a width of the second sub-pattern, and an area of the first sub-hole can be greater than an area of the second sub-hole. In addition, the first conductive mesh pattern 170 can further include a third sub-pattern between the first and second sub-patterns, and the first hole H1 can further include a third sub-hole between the first and second sub-holes. In this situation, a width of the third sub-pattern can be greater than a width of the first sub-pattern and smaller than a width of the second sub-pattern, and an area of the third sub-hole can be smaller than an area of the first sub-hole and greater than an area of the second sub-hole.

FIG. 7 is a schematic cross-sectional view illustrating a display device in a non-display area according to a fifth embodiment of the present disclosure. FIG. 7 is a schematic cross-sectional taken along the line I-I′ of FIG. 3A. Elements between the substrate 102 and the first planarization layer 141, the gate driving unit, the first and second dams and the low potential voltage line are omitted for convenience of explanation.

Referring to FIGS. 3A and 7, the planarization layer 140 including the first planarization layer 141 and the second planarization layer 143 is disposed over the substrate 102.

The conductive mesh pattern including the first, second and third conductive mesh patterns 170, 172 and 174 are disposed on the second planarization layer 143. The first conductive mesh pattern 170 is positioned in the first mesh area M1, the second conductive mesh pattern 172 is positioned in the second mesh area M2, and the third conductive mesh pattern 174 is positioned in the bank open area BOA.

The first, second and third conductive mesh patterns 170, 172 and 174 respectively include first, second and third holes H1, H2 and H3 so that a portion of the second planarization layer 143 in the first mesh pattern M1, the second mesh pattern M2 and the bank open area BOA is exposed. Namely, the first, second and third holes H1, H2 and H3 serve as an out-gassing path for the planarization layer 140.

The bank 554 is disposed in the first and second mesh areas M1 and M2 to cover the first and second conductive mesh patterns 170 and 172. The bank 554 is provided on an entire surface of the first mesh area M1 to cover the first conductive mesh pattern 170. The bank 554 is provided on an entire surface of the second mesh area M2 to cover the second conductive mesh pattern 172. The bank 554 is not provided in the bank open area BOA so that the third conductive mesh pattern 174 is not covered by the bank 554 and exposed.

A spacer 580 is disposed in the first mesh pattern M1 to correspond to the bank 554. The spacer 580 can have the same thickness as the bank 554. For example, the spacer 580 can be formed of an inorganic insulating material, e.g., silicon oxide or silicon nitride, or an organic insulating material, e.g., photo-acryl, BCB or polyimide.

The spacer 580 is disposed to correspond to the first conductive mesh pattern 170 and a space between the first conductive mesh patterns 170, e.g., the first hole H1. Namely, in the display device 500 according to the fifth embodiment of the present disclosure, the spacer 580 is disposed to cover an entire surface of the first mesh area M1. For example, the spacer 580 can cover an entire surface of the bank 554 in the first mesh area M1.

In FIG. 7, the first conductive mesh pattern 170 has the same width or spacing as the second conductive mesh pattern 172. Accordingly, the first hole H1 of the first conductive mesh pattern 170 has the same area as the second hole H2 of the second conductive mesh pattern 172. Alternatively, the first conductive mesh pattern 170 can have a width being smaller than the second conductive mesh pattern 172, and the first hole H1 can have an area greater than an area of the second hole H2.

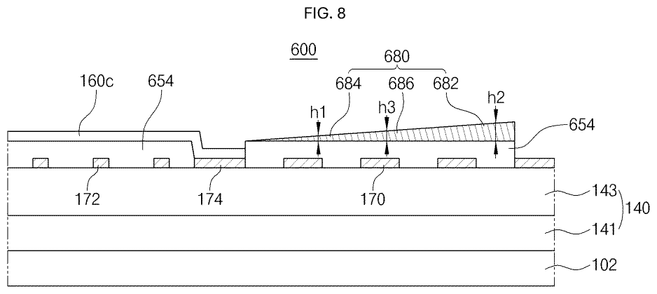

FIG. 8 is a schematic cross-sectional view illustrating a display device in a non-display area according to a sixth embodiment of the present disclosure. FIG. 8 is a schematic cross-sectional taken along the line I-I′ of FIG. 3A. Elements between the substrate 102 and the first planarization layer 141, the gate driving unit, the first and second dams and the low potential voltage line are omitted for convenience of explanation.

Referring to FIGS. 3A and 8, the planarization layer 140 including the first planarization layer 141 and the second planarization layer 143 is disposed over the substrate 102.

The conductive mesh pattern including the first, second and third conductive mesh patterns 170, 172 and 174 are disposed on the second planarization layer 143. The first conductive mesh pattern 170 is positioned in the first mesh area M1, the second conductive mesh pattern 172 is positioned in the second mesh area M2, and the third conductive mesh pattern 174 is positioned in the bank open area BOA.

The first, second and third conductive mesh patterns 170, 172 and 174 respectively include first, second and third holes H1, H2 and H3 so that a portion of the second planarization layer 143 in the first mesh pattern M1, the second mesh pattern M2 and the bank open area BOA is exposed. Namely, the first, second and third holes H1, H2 and H3 serve as an out-gassing path for the planarization layer 140.

The bank 654 is disposed in the first and second mesh areas M1 and M2 to cover the first and second conductive mesh patterns 170 and 172. The bank 654 is provided on an entire surface of the first mesh area M1 to cover the first conductive mesh pattern 170. The bank 654 is provided on an entire surface of the second mesh area M2 to cover the second conductive mesh pattern 172. The bank 654 is not provided in the bank open area BOA so that the third conductive mesh pattern 174 is not covered by the bank 654 and is exposed by the bank 654.

A spacer 680 is disposed in the first mesh pattern M1 to correspond to the bank 654. The spacer 680 can have the same thickness as the bank 654, but embodiments are not limited thereto. For example, a cross section of the spacer 680 can have a ramp shape or a triangular shape that increases in thickness as a distance away from the display area increases. For example, the spacer 680 can be formed of an inorganic insulating material, e.g., silicon oxide or silicon nitride, or an organic insulating material, e.g., photo-acryl, BCB or polyimide.

The spacer 680 is disposed to correspond to the first conductive mesh pattern 170 and a space between the first conductive mesh patterns 170, e.g., the first hole H1. Namely, in the display device 600 according to the sixth embodiment of the present disclosure, the spacer 680 is disposed to cover an entire surface of the first mesh area M1.

The spacer 680 can include a first spacer 682 and a second spacer 684 between the first spacer 682 and the bank open area BOA. The first spacer 682 can have a first height h1, and the second spacer 684 can have a second height h2 being smaller than the first height h1.

In addition, the spacer 680 can further include a third spacer 686 between the first and second spacers 682 and 684. The third spacer 686 can have a third height h3 being smaller than the first height h1 and greater than the second height h2.

In an aspect of the present disclosure, a height of the spacer 680 can be gradually increased along the first direction X as a distance away from the display area increases.

The cathode 160c of the light emitting diode D extends into the second mesh area M2 and the bank open area BOA. Namely, the extending portion of the cathode 160c covers the bank 454 in the second mesh area M2 and contacts the third conductive mesh pattern 174 in the bank open area BOA. The cathode 160c is connected to the low potential voltage line 176 (of FIG. 3B) through the third conductive mesh pattern 174 and the first conductive mesh pattern 170 so that the low potential voltage can be applied to the cathode 160c. A portion, which contacts the third conductive mesh pattern 174, of the cathode 160c can be referred to as a contact electrode.

In FIG. 8, the first conductive mesh pattern 170 has the same width or spacing as the second conductive mesh pattern 172. Accordingly, the first hole H1 of the first conductive mesh pattern 170 has the same area as the second hole H2 of the second conductive mesh pattern 172. Alternatively, the first conductive mesh pattern 170 can have a width being smaller than the second conductive mesh pattern 172, and the first hole H1 can have an area greater than an area of the second hole H2.

In FIG. 8, the first conductive mesh pattern 170 has the same, e.g., constant, width, and the first hole H1 has the same, e.g., constant, area. Alternatively, as illustrated in FIGS. 4A and 4B, the first conductive mesh pattern 170 can include a first sub-pattern and a second sub-pattern between the first sub-pattern and the bank open area BOA, and the first hole H1 can include a first sub-hole and a second sub-hole between the first sub-hole and the bank open area BOA. In this situation, a width of the first sub-pattern can be smaller than a width of the second sub-pattern, and an area of the first sub-hole can be greater than an area of the second sub-hole. In addition, the first conductive mesh pattern 170 can further include a third sub-pattern between the first and second sub-patterns, and the first hole H1 can further include a third sub-hole between the first and second sub-holes. In this situation, a width of the third sub-pattern can be greater than a width of the first sub-pattern and smaller than a width of the second sub-pattern, and an area of the third sub-hole can be smaller than an area of the first sub-hole and greater than an area of the second sub-hole.

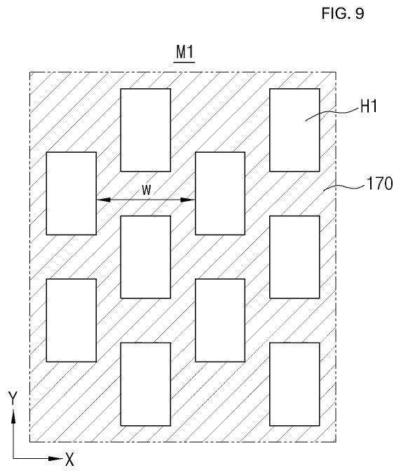

FIG. 9 is a schematic plane view illustrating a display device in a non-display area according to a seventh embodiment of the present disclosure.

As shown in FIG. 9, a first conductive mesh pattern 170 including a first hole H1 is disposed in a first mesh area M1 being a portion of a non-display area. The first holes H1 are spaced apart from each other in a first direction X and a second direction Y.

The first holes H1 are alternately arranged in the first direction X. For example, in the second direction Y, the first hole H1 in a first column can correspond to a space between adjacent first holes H1 in a second column.

In the display device according to the seventh embodiment of the present disclosure, a width w of the first conductive mesh pattern 170 is increased so that a resistance of the first conductive mesh pattern 170 is decreased. Accordingly, the delay of the low potential signal into the cathode 160c (of FIG. 2) can be prevented.

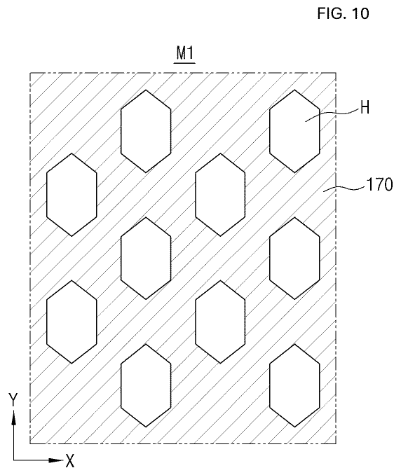

FIG. 10 is a schematic plane view illustrating a display device in a non-display area according to an eighth embodiment of the present disclosure.

As shown in FIG. 10, a first conductive mesh pattern 170 including a first hole H1 is disposed in a first mesh area M1 being a portion of a non-display area. The first holes H1 are spaced apart from each other in a first direction X and a second direction Y.

The first hole H1 has a shape with pointed opposite ends. For example, the first hole H1 can have a hexagonal shape. However, embodiments are not limited thereto and the first hole H1 can have other shapes such as a circle, an oval, a square, a triangle, a polygon that has five or more sides, and a shape with rounded corners.

The first holes H1 are alternately arranged in the first direction X. For example, in the second direction Y, the first hole H1 in a first column can correspond to a space between adjacent first holes H1 in a second column. In this situation, the first holes H1 are arranged so that the pointed end of one of the first hole H1 and the pointed end of adjacent one of the first hole H1 face each other.

Referring to FIG. 3B, the encapsulating layer 162 including the organic layer 162b is disposed over the substrate 102 including the first conductive mesh pattern 170, and the organic layer 162b can be formed by a solution process.

When the first holes H1 are arranged so that the pointed end of one of the first hole H1 and the pointed end of adjacent one of the first hole H1 face each other as the display device according to the eighth embodiment of the present disclosure, the solution for forming the organic layer 162b dropped between adjacent first holes H1 can be uniformly spread. Accordingly, the encapsulation layer 162 can be uniformly formed, and the damage of the display device by penetration of moisture and/or oxygen can be minimized or prevented.

It will be apparent to those skilled in the art that various modifications and variations can be made in the embodiments of the present disclosure without departing from the spirit or scope of the present disclosure. Thus, it is intended that the modifications and variations cover this disclosure provided they come within the scope of the appended claims and their equivalents.

What is claimed is:

1. A display device, comprising:
a substrate including a display area and a non-display area at an outer side of the display area, the non-display area including a first mesh area, a second mesh area between the first mesh area and the display area and a bank open area between the first mesh area and the second mesh area;
a light emitting diode disposed in the display area and including an anode, a light emitting layer and a cathode;
a conductive mesh layer including a first conductive mesh pattern in the first mesh area, a second conductive mesh pattern in the second mesh area and a third conductive mesh pattern in the bank open area;
a bank disposed in the first and second mesh areas and exposing the third conductive mesh pattern in the bank open area;
a contact electrode overlapping with the bank in the second mesh area and connected to the third conductive mesh pattern in the bank open area; and
a spacer disposed on the bank in the first mesh area.

2. The display device according to claim 1, wherein the bank is positioned between portions of the first conductive mesh pattern and exposes the portions of the first conductive mesh pattern in the first mesh area, and
wherein the spacer is positioned on the bank between the portions of the first conductive mesh pattern.

3. The display device according to claim 1, wherein the first conductive mesh pattern has a first width, and the second conductive mesh pattern has a second width smaller than the first width of the first conductive mesh pattern.

4. The display device according to claim 1, wherein a first hole in the first conductive mesh pattern has a first area, and a second hole in the second conductive mesh pattern has a second area greater than the first area of the first hole in the first conductive mesh pattern.

5. The display device according to claim 1, wherein the spacer includes a first spacer and a second spacer between the first spacer and the bank open area, and
wherein the first spacer has a first height, and the second spacer has a second height smaller than the first height of the first spacer.

6. The display device according to claim 5, wherein the first conductive mesh pattern includes a first sub-pattern and a second sub-pattern between the first sub-pattern and the bank open area, and
wherein the first sub-pattern has a first width, and the second sub-pattern has a second width greater than the first width.

7. The display device according to claim 6, wherein the spacer further includes a third spacer between the first and second spacers, and
wherein the third spacer has a third height smaller than the first height and greater than the second height.

8. The display device according to claim 7, wherein the first conductive mesh pattern further includes a third sub-pattern between the first and second sub-patterns, and
wherein the third sub-pattern has a third width greater than the first width and smaller than the second width.

9. The display device according to claim 1, wherein the bank covers an entire surface of the first conductive mesh pattern.

10. The display device according to claim 9, wherein the spacer overlaps with the first conductive mesh pattern.

11. The display device according to claim 9, wherein the spacer corresponds to a space between the portions of the first conductive mesh pattern.

12. The display device according to claim 9, wherein the spacer corresponds to an entire surface of the first conductive mesh pattern.

13. The display device according to claim 12, wherein the spacer includes a first spacer and a second spacer between the first spacer and the bank open area, and
wherein the first spacer has a first height, and the second spacer has a second height smaller than the first height.

14. The display device according to claim 13, wherein the first conductive mesh pattern has a first width that corresponds to the first spacer and a second width that corresponds to the second spacer, and the second width is greater than the first width.

15. The display device according to claim 13, wherein the spacer further includes a third spacer between the first and second spacers, and
wherein the third spacer has a third height smaller than the first height and greater than the second height.

16. The display device according to claim 15, wherein the first conductive mesh pattern has a third width that corresponds to the third spacer, and
wherein the third width of the first conductive mesh pattern is greater than the first width of the first conductive mesh pattern and smaller than the second width of the first conductive mesh pattern.

17. The display device according to claim 1, further comprising:
a low potential voltage line at an outer side of the first mesh area,
wherein the contact electrode extends from the cathode, and
wherein an end of the first conductive mesh pattern is connected to the low potential voltage line so that the cathode is electrically connected to the low potential voltage line.

18. The display device according to claim 1, further comprising:
an encapsulation layer covering the light emitting diode in the display area, the spacer in the first mesh area, the contact electrode in the second mesh area and the bank open area.

19. The display device according to claim 1, wherein a plurality holes in the first conductive mesh pattern are alternatively arranged with each other.

20. The display device according to claim 1, wherein each of a plurality of holes in the conductive mesh layer has a pointed end, and
wherein in at least one direction, adjacent holes among the plurality of holes in the conductive mesh layer are arranged so that the pointed ends of the adjacent holes face each other.

21. A display device, comprising:
a plurality of subpixels disposed in a display area of a substrate;
a conductive mesh layer disposed in a non-display area of the substrate, the conductive mesh layer including a plurality of holes;
at least one subpixel among the plurality of subpixels including a first electrode, a second electrode and a light emitting layer disposed between the first electrode and the second electrode; and
at least one spacer disposed on the conductive mesh layer or overlapping with one of the plurality of holes in the conductive mesh layer,
wherein at least one of the first electrode and the second electrode is electrically connected to the conductive mesh layer in the non-display area,
wherein the at least one spacer includes an insulating material, and
wherein an upper surface of the at least one spacer is positioned higher than an upper surface of the conductive mesh layer.

22. The display device according to claim 21, wherein the conductive mesh layer includes a first region, a second region closer to the display area than the first region, and a third region between the first region and the second region,
wherein the plurality of holes in the conductive mesh layer includes a first group of holes in the first region, a second group of holes in the second region and a third group of holes in the third region, and
wherein a first hole among the first group of holes in the first region is larger than a second hole among the second group of holes in the second region.

23. The display device according to claim 21, further comprising:
a bank layer disposed in the first region and the second region,
wherein the third region is a bank open area corresponding to an open area of the bank layer.

24. The display device according to claim 23, wherein the at least one spacer includes a plurality of spacers disposed on portions of the bank layer in the first region.

25. The display device according to claim 21, wherein a thickness of the at least one spacer increases as a distance away from the display area increases.
